(19) United States
(12) Patent Application Publication
(10) Pub. No.: US 2025/0199412 A1
(43) Pub. Date: Jun. 19, 2025

(54) METHOD OF INCREASING CROSSLINKING DENSITY OF PHOTORESIST

(71) Applicant: TAIWAN SEMICONDUCTOR MANUFACTURING COMPANY, LTD., Hsinchu (TW)

(72) Inventors: Yuan Chih LO, Hsinchu City (TW); Chen-Yu LIU, Kaohsiung City (TW); Cheng-Han WU, Taichung City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/404,737

(22) Filed: Jan. 4, 2024

Related U.S. Application Data
(60) Provisional application No. 63/611,213, filed on Dec. 18, 2023.

(51) Int. Cl. G03F 7/40; G03F 7/004; G03F 7/20; G03F 7/32; G03F 7/38

(52) U.S. Cl. CPC G03F 7/405; G03F 7/0042; G03F 7/32; G03F 7/38; G03F 7/2004

(57) ABSTRACT

A lithography method includes the following steps. A target layer is formed over a substrate. A photoresist composition is applied over the target layer to form a photoresist layer, wherein the photoresist composition comprises a metal-oxide based material. The photoresist layer is exposed to form an exposed region in the photoresist layer. A mixture is applied to the photoresist layer to develop the photoresist layer, wherein the step of applying the mixture to the photoresist layer increases a crosslinking density of the photoresist layer and increases a dissolution contrast of the photoresist layer during developing the photoresist layer by increasing a hydrophilicity of the exposed region. The target layer is etched using the photoresist layer as an etch mask.

### RELATED APPLICATION

This application claims priority to U.S. Provisional Patent Application Ser. No. 63/611,213, filed Dec. 18, 2023, which is herein incorporated by reference.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of an EUV lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 2 is a sectional view of a EUV mask constructed in accordance with some embodiments of the present disclosure.

FIG. 3 is a flowchart of an exemplary method for patterning a target layer in accordance with some embodiments.

FIGS. 4, 5, 6, 7A, 8A, 10, 11 and 12 are cross-sectional views of a semiconductor device at various stages of the method of FIG. 3 in accordance with various aspects of the present disclosure.

FIG. 7B is a structure of the photoresist layer after being exposed in accordance with some embodiments.

FIG. 8B is a structure of the photoresist layer after being treated to have an increased crosslinking density in accordance with some embodiments.

FIG. 9 shows a principle of increasing a crosslinking density of the photoresist layer.

FIG. 13A is a flowchart of a method for patterning a target layer in accordance with some embodiments.

FIGS. 13B, 14A, 15 and 16 are cross-sectional views of a semiconductor device at various stages of the method of FIG. 13A in accordance with various aspects of the present disclosure.

FIG. 14B is an enlarged view of a target layer 112a in FIG. 14A.

FIGS. 17-20 are cross-sectional views of a semiconductor device in an intermediate stage of fabrication in accordance with some embodiments of the present disclosure.

FIG. 21A is a perspective view of the semiconductor device in an intermediate stage of fabrication in accordance with some embodiments of the present disclosure.

FIGS. 21B and 21C are cross-sectional views along line a1-a1 and line b1-b1 of FIG. 21A, respectively, in accordance with various aspects of the present disclosure.

FIGS. 22-25 are cross-sectional views of the semiconductor device in an intermediate stage of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

Extreme ultraviolet (EUV) lithography is used for manufacturing advanced integrated circuit chips. However, further pitch shrinkage is challenging for conventional photoresist, especially chemically amplified reaction (CAR) resist, owing to an intrinsic characteristic, such as low modulus and limited etch-resistant ability of the CAR resist. An EUV light sensitivity of the CAR resist is also limited owing to an atomic absorption efficiency thereof. To this, several types of metal-oxide resist based on Ti, Ir, Hf, Sn, Al, Cu are developed for their high mechanical strength and high sensitivity to the EUV light.

Photolithography process may include several steps such as applying photoresist on a substrate followed by an exposure using electromagnetic wave through a reticle or mask, a post exposure baking (PEB) and a development step to reveal a designed pattern. In the exposure, the photoresist may absorb electromagnetic wave to an excited state, generating secondary electrons and radicals along with dissociation of organic ligands, which are originally attached on the metal-oxide resist. After the exposure, the PEB may be applied to intensify the reaction and render the metal-oxide resist dehydrate, aggregate and become insoluble to developer or etching-gas-resistant. Strength of the photoresist after the development step is crucial for mitigating the designed pattern, such as a line, of the photoresist from being broken or peeling.

The present disclosure provides a method of increasing a crosslinking density of a photoresist layer such that the photoresist layer can have an enhanced mechanical strength to etching or bombardment using ion, elements, plasma, or the like.

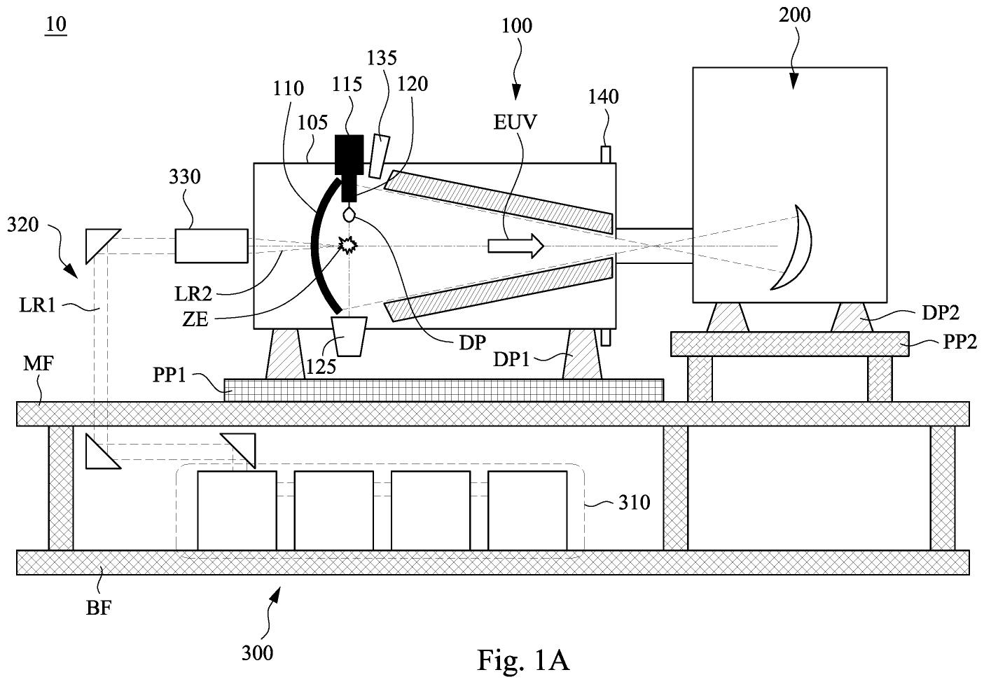

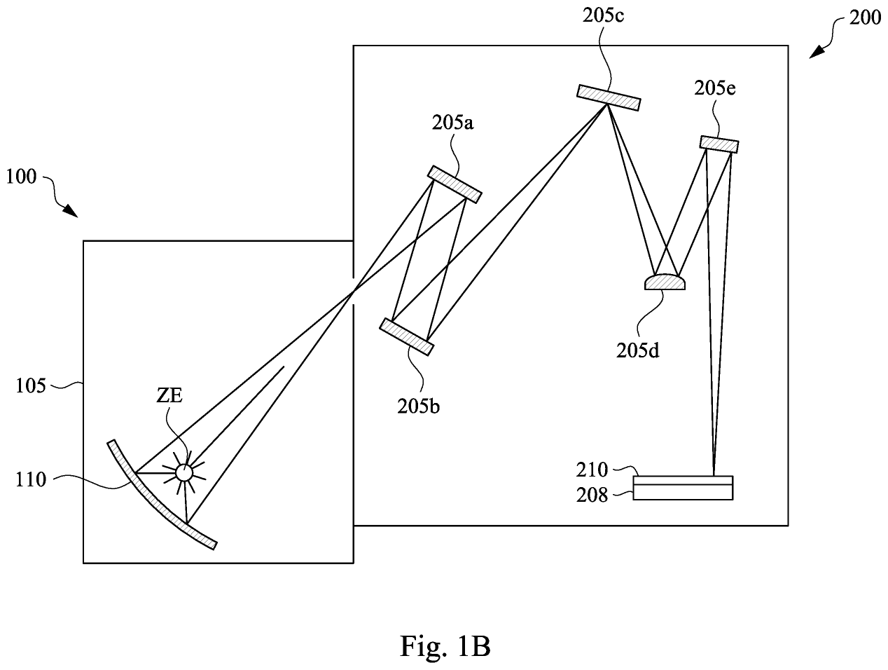

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by an EUV light or EUV radiation. The EUV lithography system 10 employs a radiation source 100 to generate EUV light, such as EUV light having a wavelength ranging between about 1 nm and about 100 nm. In one particular example, the radiation source 100 generates a EUV light with a wavelength centered at about 13.5 nm. Accordingly, the radiation source 100 is also referred to as EUV radiation source 100.

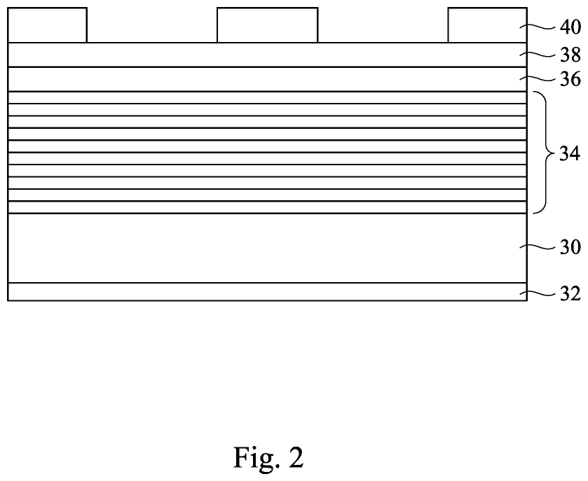

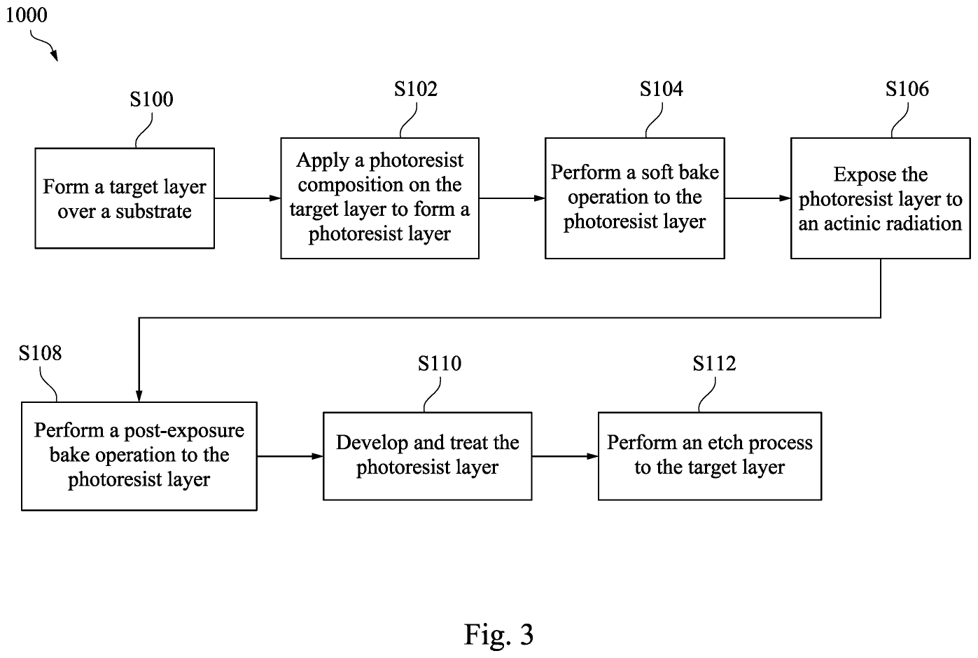

The various aspects of the present disclosure will be discussed below in greater detail with reference to FIGS. 1A-25. First, an EUV lithography system will be discussed below with reference to FIGS. 1A, 1B and 2. Next, the details of the lithography process will be discussed with reference to FIGS. 3-25.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1B, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength. In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 2. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 2, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: Actium, Radium, Tellurium, Zinc, Copper, and Aluminum.

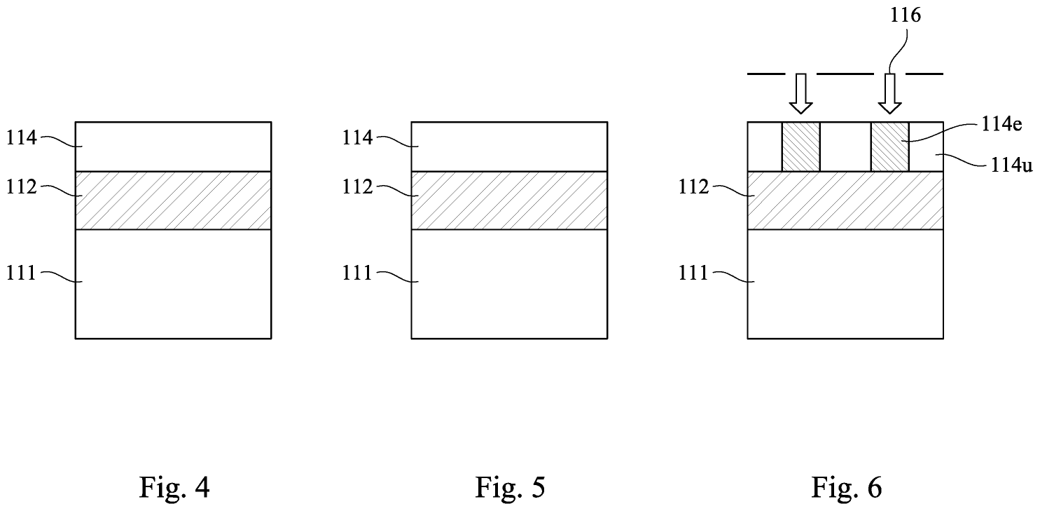

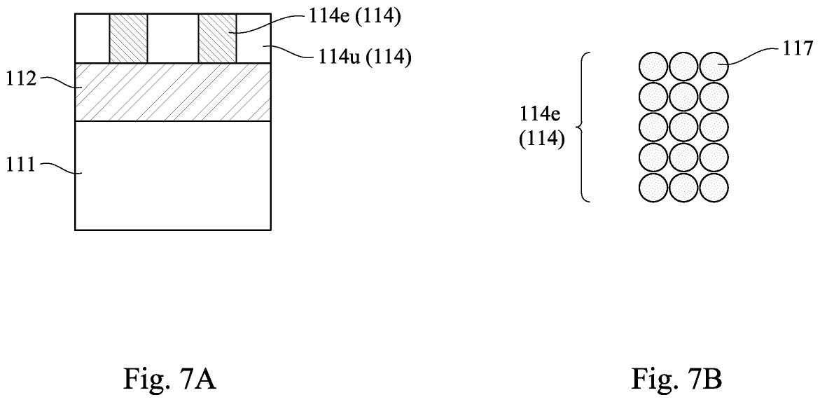

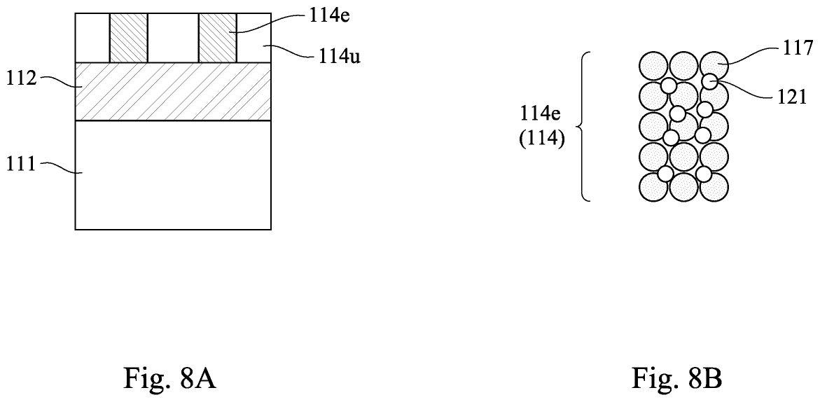

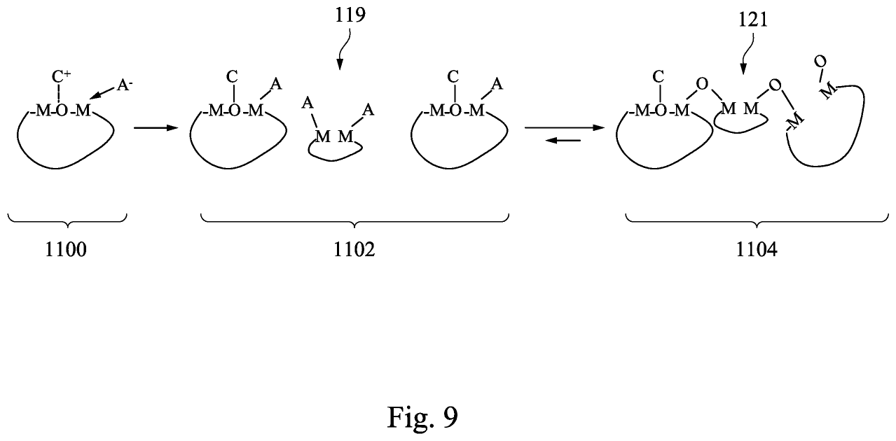

FIG. 3 is a flowchart of a method 1000 for patterning a target layer in accordance with some embodiments. FIGS. 4, 5, 6, 7A, 8A, 10, 11 and 12 are cross-sectional views of a semiconductor device at various stages of the method 1000 of FIG. 3 in accordance with various aspects of the present disclosure. FIG. 7B is a structure of the photoresist layer after being exposed in accordance with some embodiments. FIG. 8B is a structure of the photoresist layer after being treated to have an increased crosslinking density in accordance with some embodiments. FIG. 9 shows a principle of increasing a crosslinking density of the photoresist layer.

The method 1000 includes a relevant part of an entire manufacturing process. It is understood that additional operations may be provided before, during and after the operations shown by FIG. 3, and some of the operations described below can be replaced or eliminated for additional embodiments of the method 1000. The order of the operations/processes may be interchangeable. The method 1000 includes fabrication of a semiconductor device. However, the fabrication of the semiconductor device is merely an example for describing the manufacturing process according to some embodiments of the present disclosure.

The method 1000 begins at operation S100 in which the operation S100 includes forming a target layer over a substrate. With reference to FIGS. 3 and 4, in some embodiments of the operation S100, a target layer 112 to be patterned is formed on a substrate 111. A photoresist composition is deposited on the target layer 112 to form a photoresist layer 114. For example, the target layer 112 may be formed by an acceptable deposition process, such as chemical vapor deposition (CVD), physical vapor deposition (PVD), atomic layer deposition (ALD), spin coating process, or the like. The substrate 111 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

In some embodiments, the substrate 111 is a silicon substrate doped with a p-type dopant such as boron (for example a p-type substrate). Alternatively, the substrate 111 could be another suitable semiconductor material. For example, the substrate 111 may be a silicon substrate that is doped with an n-type dopant such as phosphorous or arsenic (an n-type substrate). The substrate 111 could include other elementary semiconductors such as germanium and diamond. The substrate 111 could optionally include a compound semiconductor and/or an alloy semiconductor. Further, the substrate 111 could include an epitaxial layer (epi layer), may be strained for performance enhancement, and may include a silicon-on-insulator (SOI) structure.

In some embodiments, the target layer 112 is substantially conductive or semi-conductive. The electrical resistance may be less than about 103 ohm-meter. In some embodiments, the target layer 112 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the target layer 112 may contain Ti, Al, Co, Ru, TiN, WN₂, or TaN.

In some other embodiments, the target layer 112 contains a dielectric material with a dielectric constant in a range from about 1 to about 40. In some other embodiments, the target layer 112 contains Si, metal oxide, or metal nitride, where the formula is MX_{b}, wherein M is a metal or Si, and X is N or O, and wherein “b” is in a range from about 0.4 to 2.5. For example, the target layer 112 may contain SiO₂, silicon nitride, aluminum oxide, hafnium oxide, or lanthanum oxide.

The method 1000 then proceeds to operation S102 in which the operation S102 includes applying a photoresist composition on the target layer to form a photoresist layer. Still with reference to FIGS. 3 and 4, in some embodiments of the operation S102, a photoresist composition is applied on the target layer 112 to form a photoresist layer 114. The photoresist composition applied on the target layer 112 to form the photoresist layer 114 may be applied by spin coating process or deposition process. The photoresist composition may include a solvent and a metal-oxide based material dissolved in the solvent. In some embodiments, the metal-oxide based material is an organometallic compound, such as transition metal complexes characterized with coordination numbers that range from 1 to 12. When exposed to actinic radiation, the photoresist layer 114 undergoes one or more chemical reactions causing a change in solubility in a developer. In some embodiments, the metal-oxide based material is made of oxide of Ti, Ir, Hf, Sn, Al, Cu or a combination thereof.

The method 1000 then proceeds to operation S104 in which the operation S104 includes perform a soft bake operation to the photoresist layer. With reference to FIGS. 3 and 5, in some embodiments of the operation S104, a soft bake (SB) process S104 is performed to the photoresist layer 114 to reduce the solvent in the photoresist layer 114. For example, the solvent may be partially evaporated by the soft bake process.

The method 1000 proceeds to operation S106 in which the operation S106 includes exposing the photoresist layer to an actinic radiation. With reference to FIGS. 3 and 6, in some embodiments of the operation S106, the photoresist layer 114 is exposed to an actinic radiation 116. In some embodiments, the photoresist layer 114 is exposed to the actinic radiation 116 with an illumination wavelength which is substantially less than about 250 nm. For example, the actinic radiation 116 may include at least one of the KrF, ArF, extreme ultraviolet (EUV) radiation, E-beam or the like. The photoresist layer 114 may include an exposed region 114e and an unexposed region 114u.

The method 1000 proceeds to operation S108 in which the operation S108 includes performing a post-exposure bake (PEB) operation to the photoresist layer. With reference to FIGS. 3, 7A and 7B, in some embodiments of the operation S108, a post-exposure bake operation is performed to the photoresist layer 114. The PEB operation is performed to intensify the reaction and render the metal-oxide based material of the photoresist layer 114 dehydrate, aggregate and become insoluble to developer or etching-gas-resistant. For example, after the PEB operation is performed to the photoresist layer 114, a first structure of the photoresist layer 114 becomes a cluster. As shown in FIG. 7B, the first structure of the exposed region 114e of the photoresist layer 114 may be clusters 117 of the metal-oxide resist and have a first density. The first structure of the exposed region 114e of the photoresist layer 114 includes the clusters 117 of the metal-oxide resist with metal-oxygen-metal (M-O-M) bonds.

The method 1000 proceeds to operation S110 in which the operation S110 includes developing and treating the photoresist layer. With reference to FIGS. 3 and 8A, in some embodiments of the operation S110, the photoresist layer 114 is subsequently developed and treated at the same time by applying a mixture of chemical substances to the photoresist layer 114. In some embodiments, the mixture includes a developer such as a solvent-based solution which is a negative tone developer (NTD), such as n-butyl acetate (nBA). The developer in the mixture is configured to develop the photoresist layer 114. For example, the unexposed region 114u of the photoresist layer 114 may be removed by the developer while the exposed region 114e of the photoresist layer 114 remains.

The mixture further includes a non-developer such as an additive in some embodiments. Treating the photoresist layer 114 using the mixture including the additive allows the photoresist layer 114 to undergo stages 1100, 1102 and 1104 in FIG. 9. In some embodiments, the additive is made of a cation C⁺ and an anion A. As mentioned above, the structure of the exposed region 114e of the photoresist layer 114 includes the clusters 117 of the metal-oxide resist with metal-oxygen-metal (M-O-M) bonds. At the stage 1100, the cation C⁺ of the additive may bond to a metal-oxygen-metal (M-O-M) cite and the anion A⁻ of the additive would attack a metal-oxygen (M-O) bond and form metal-A (M-A) bonds, resulting in the stage 1102. At the stage 1102, the M-O-M bonds are thus opened, and a chemical substance 119 including M-A bonds is present. In other words, the chemical substance 119 includes the anion of the additive. Since the M-A bonds have strength smaller than strength of the M-O bonds, a reverse reaction will take place to form a cross-cluster metal-oxygen-metal (M-O-M) bond, as shown in the stage 1104. Since some of the cation C⁺ and the anion A⁻ remain in the photoresist layer 114, the stages 1102 and 1104 will occur repeatedly and eventually form a pattern with a crosslinked framework or crosslinked structure between metal-oxygen-metal (M-O-M) atoms in the stage 1104 rather than crosslinking between clusters of the metal-oxide resist. The first structure of the photoresist layer 114 becomes a second structure in FIG. 8B, which is different from the first structure in FIG. 7B. The second structure is made of the clusters 117 and photoresist segments 121. Therefore, the second structure of the exposed region 114e of the photoresist layer 114 in FIG. 8B has a second density greater than the first density of the first structure of the photoresist layer 114 in FIG. 7B. In other words, the exposed region 114e of the photoresist layer 114 can have an increased crosslinking density such that the exposed region 114e of the photoresist layer 114 has an enhanced mechanical strength to etching or bombardment using ion, elements, plasma, or the like.

In some embodiments, the additive used to treat the photoresist layer 114 is at an aqueous solution state, a non-aqueous solution state, a liquid state, a gaseous state, or a plasma state under a temperature in a range from −50° C. to 300° C. and under a pressure of 10 mTorr to 7600 mTorr. In some embodiments, the additive can be a pure substance at a gas state, a solid state, or a liquid state in the operation S110, and can be a mixture at a gas state, a solid state, or a liquid state in the operation S110. In some embodiments, during the operation S110, the additive is used without being dissolved in a solvent. In other words, the additive is used alone. In some embodiments, during the operation S110, the additive is used as being dissolved in a water or an organic solvent including (cyclic) alcohols, (cyclic) ketones, (cyclic) esters, (cyclic) ethers, (cyclic) amides, aryls, (cyclic) alkane. For example, the organic solvent may be Propylene glycol methyl ether, Propylene glycol methyl ether acetate, Diacetone alcohol, Methyl N-Amyl Ketone Butyl acetate, gamma-Butyrolactone, Cyclohexanone, toluene, 1-Methyl-2-pyrrolidone, the like, or a mixture with an arbitrary ratio of the organic solvent listed above.

In some embodiments, the additive used to treat the photoresist layer 114 can be an inorganic acid, for example, HF, HCl, HBr, HI, H₃PO₄, HNO₃, HNO₂, H₂SO₄, H₂SO₃, HClO₄, HClO₃, HBrO₄, HBrO₃, HIO₄, HIO₃, H₃PO₄, H₃PO₃, H₂S, R—COOH, Methanesulfonic acid, the like, or a combination thereof.

In some embodiments, the additive used to treat the photoresist layer 114 can be an organic acid such as R—COOH, where R in the R—COOH can be branched, unbranched or cyclic alkane, alkene or alkyne, aryls with hydroxyl group or halogen substitution.

In some embodiments, the cation of the additive used to treat the photoresist layer 114 can include H⁺, Li⁺, Na⁺, K⁺, Be²⁺, Mg²⁺, Ca²⁺, Ti⁴⁺, Fe²⁺, Fe³⁺, Cr³⁺, Cr⁶⁺, Ni²⁺, Ni³⁺, Cu²⁺, Cu²⁺, Ag⁺, Pd²⁺, Pd⁴⁺, Au²⁺, Au⁺, Zn²⁺, B³⁺, Al³⁺, Sn²⁺, Sn³⁺, Sn⁴⁺, Si⁴⁺, N⁺R₁R₂R₃R₄, or a combination thereof, in which R₁, R₂, R₃ and R₄ can individually be branched, unbranched or cyclic alkane, alkene or alkyne with 1 to 5 carbon atoms.

Therefore, the exposed region 114e of the photoresist layer 114 has a structure including clusters of metal-oxide resist, and the clusters of metal-oxide resist bond to H, Li, Na, K, Be, Mg, Ca, Ti, Fe, Fe, Cr, Cr, Ni, Ni, Cu, Cu, Ag, Pd, Pd, Au, Au, Zn, B, Al, Sn, Sn, Sn, Si, N⁺R₁R₂R₃R₄, or a combination thereof, in which R₁, R₂, R₃ and R₄ is individually branched, unbranched or cyclic alkane, alkene or alkyne with 1 to 5 carbon atoms (see the stage 1104 in FIG. 9).

In some embodiments, the anion of the additive used to treat the photoresist layer 114 can include F⁻, Cl⁻, Br⁻, I⁻, OH⁻, CN⁻, SCN⁻, NO₃⁻, NO₂⁻, SO₄⁻², SO₃⁻², ClO₄⁻, ClO₃⁻, BrO₄⁻, BrO₃⁻, IO₄⁻, IO₃⁻, PO₄⁻³, PO₃⁻², S⁻², HS⁻, SR⁻, in which R can be branched, unbranched or cyclic alkane, alkene or alkyne with 1 to 5 carbon atoms, OR⁻, in which R is branched, unbranched or cyclic alkane, alkene or alkyne with 1 to 5 carbon atoms, or a combination thereof. In some embodiments, the additive used to treat the photoresist layer 114 can be elements including F₂, Cl₂, Br₂, I₂, H₂, Al, Fe, Ni, Cu, Ti, Zn, Cu, He, Ne, Ar, O₂, O₃, the like, or a combination thereof.

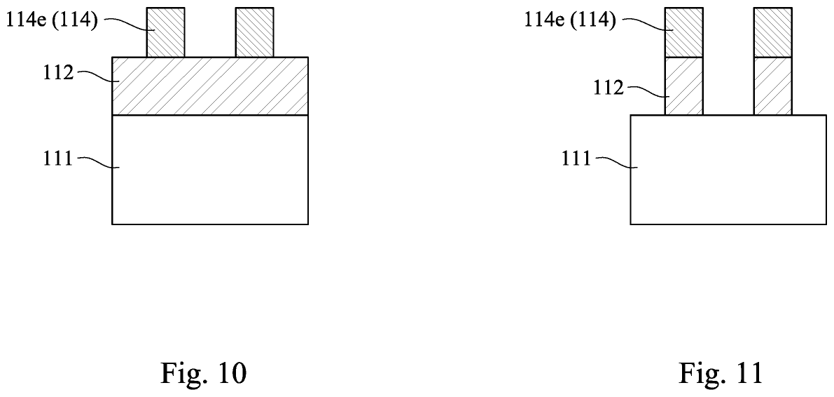

Reference is made to FIG. 10. The exposed region 114e of the photoresist layer 114 has a minimum line width with a critical dimension (CD) that is not broken. For example, in the step S110 in FIG. 3, when the additive has a first concentration in the mixture, the exposed region 114e can have a minimum line width with a CD that is 0.9 times of a CD of a minimum line width of an exposed region without using the additive of the present disclosure. In some other embodiments, in the step S110 in FIG. 3, when the additive has a second concentration in the mixture that is 2 times of the first concentration, the exposed region 114e can have a minimum line width with a CD that is 0.8 times of the CD of a minimum line width of an exposed region without using the additive of the present disclosure.

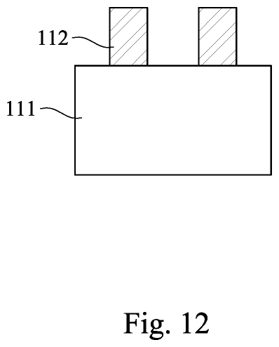

The method 1000 proceeds to operation S112 in which the operation S112 includes performing an etch process to the target layer. With reference to FIGS. 3 and 11, in some embodiments of the operation S112, an etch process is performed to the target layer 112 using the exposed region of the photoresist layer 114 as an etch mask. For example, the etch process is a dry etch process including a biased plasma etch process that uses a chlorine-based chemistry, CF₄, NF₃, SF₆, or the like. The dry etch process may be performed anisotropically. The exposed region 114e of the photoresist layer 114 has the increased crosslinking density and thus has an enhanced mechanical strength to the etch process. The exposed region 114e of the photoresist layer 114 is removed after etching the target layer 112 by using a suitable photoresist stripper solvent or by a photoresist ashing operation. The resulting structure is shown in FIG. 12.

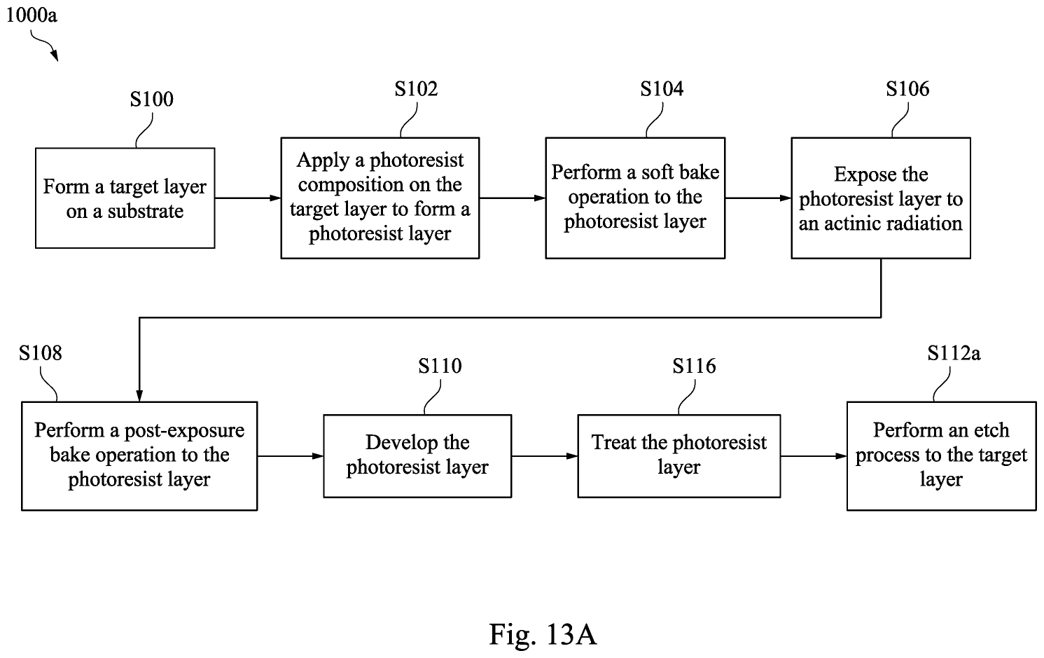

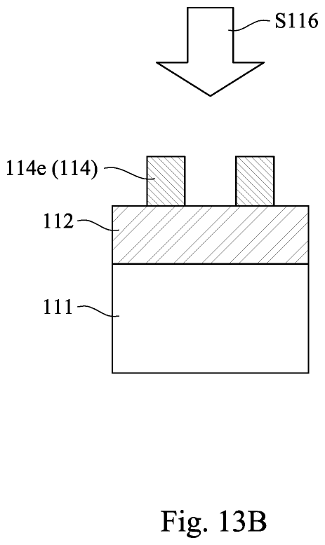

FIG. 13A is a flowchart of a method 1000a for patterning a target layer in accordance with some embodiments. FIGS. 13B, 14A, 15 and 16 are cross-sectional views of a semiconductor device at various stages of the method 1000a of FIG. 13A in accordance with various aspects of the present disclosure. The method 1000a is similar to the method 1000, except for treating the photoresist layer after developing the photoresist layer. For example, after the operation S110, the method 1000a then proceeds to operation S116 in which the operation S116 includes treating the photoresist layer. The operation S116 is performed using the additive similar to the additive as discussed previously with regard to FIGS. 3, 8A, 8B and 9. Reference is made to FIGS. 9, 13A and 13B. During the operation S116, the cation C⁺ and the anion A⁻ in the additive can be provided onto the exposed region 114e of the photoresist layer 114 to break the clusters of the metal-oxide resist and enhance the crosslinking framework between the metal-oxygen-metal (M-O-M) atoms, realizing a pattern with higher mechanical strength. In some embodiments, during the operation S116, the element A at a radical state may also be provided on the exposed region of the photoresist layer 114. By treating the exposed region 114e of the photoresist layer 114 with the additive in the operation S116, the exposed region 114e of the photoresist layer 114 can have an increased crosslinking density such that the exposed region 114e of the photoresist layer 114 has an enhanced mechanical strength to etching or bombardment using ion, elements, plasma, or the like.

The method 1000a proceeds to operation S112a in which the operation S112a includes performing an etch process to the target layer. The operation S112a is similar to the operation S112, and thus the description thereof is omitted herein. In some other embodiments, the photoresist layer 114 is treated using the additive before the PEB operation in the operation S108 or during the PEB operation in the operation S108.

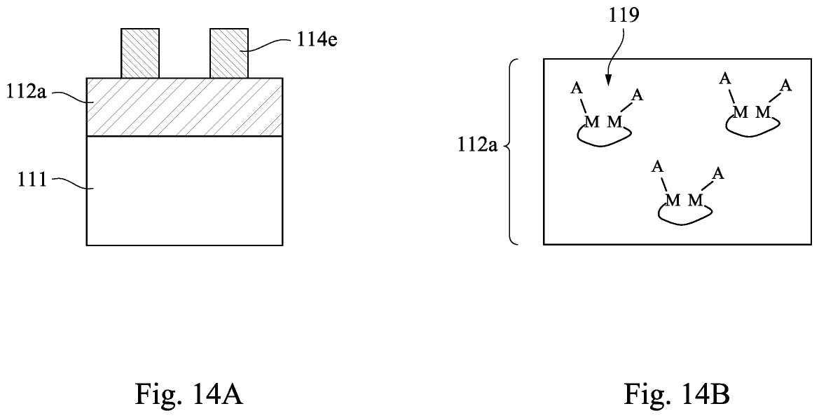

FIG. 14B is an enlarged view of a target layer 112a in FIG. 14A. Reference is made to FIGS. 14A and 14B. In some embodiments, the chemical substance 119 including the M-A bonds (see FIG. 9) may flow into or diffuse into the target layer 112a since the chemical substance 119 including the M-A bonds has a high fluidity. For example, the target layer 112a may have the chemical substance 119 randomly distributed therein. The chemical substance 119 including the M-A bonds may increase an etch resistant ability of the target layer 112a such that the target layer 112a may not collapse during etching the target layer 112a subsequently. In other words, the chemical substance 119 including the M-A bonds provides the target layer 112a an enhanced mechanical strength to etching or bombardment using ion, elements, plasma, or the like.

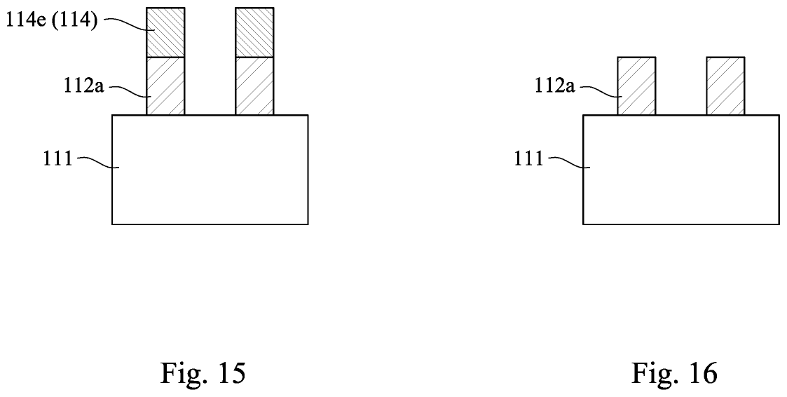

Reference is made to FIG. 15. An etch process is performed to the target layer 112a using the exposed region 114e of the photoresist layer 114 as an etch mask. For example, the etch process is a dry etch process including a biased plasma etch process that uses a chlorine-based chemistry, CF₄, NF₃, SF₆, or the like. The dry etch process may be performed anisotropically. The exposed region 114e of the photoresist layer 114 has the increased crosslinking density and thus has an enhanced mechanical strength to the etch process. The target layer 112a has the chemical substance 119, and thus may not collapse during etching the target layer 112a. The exposed region 114e of the photoresist layer 114 is removed after etching the target layer 112a by using a suitable photoresist stripper solvent or by a photoresist ashing operation. The resulting structure is shown in FIG. 16.

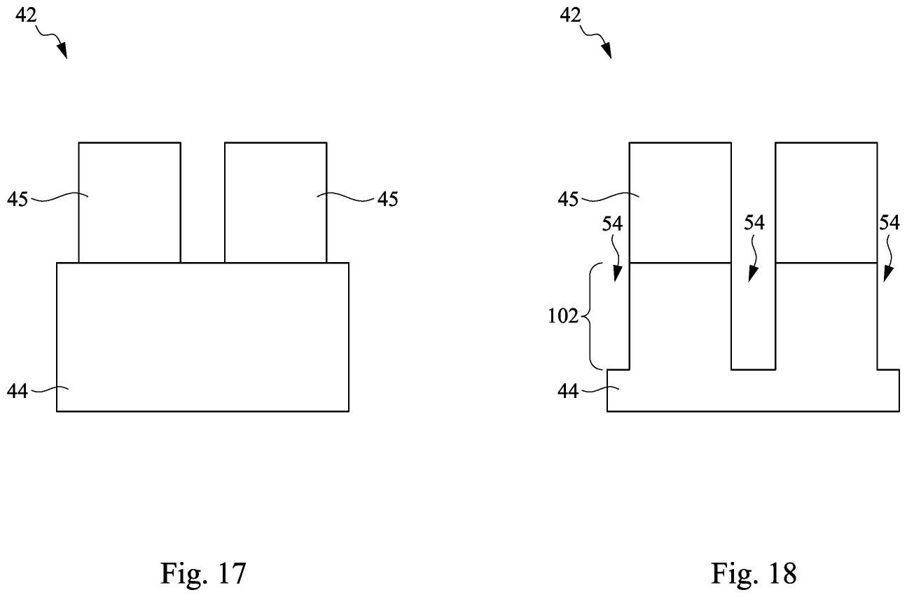

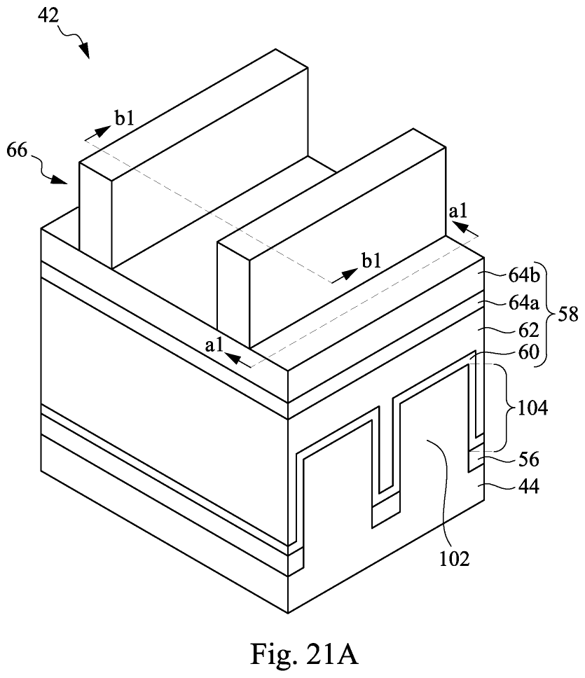

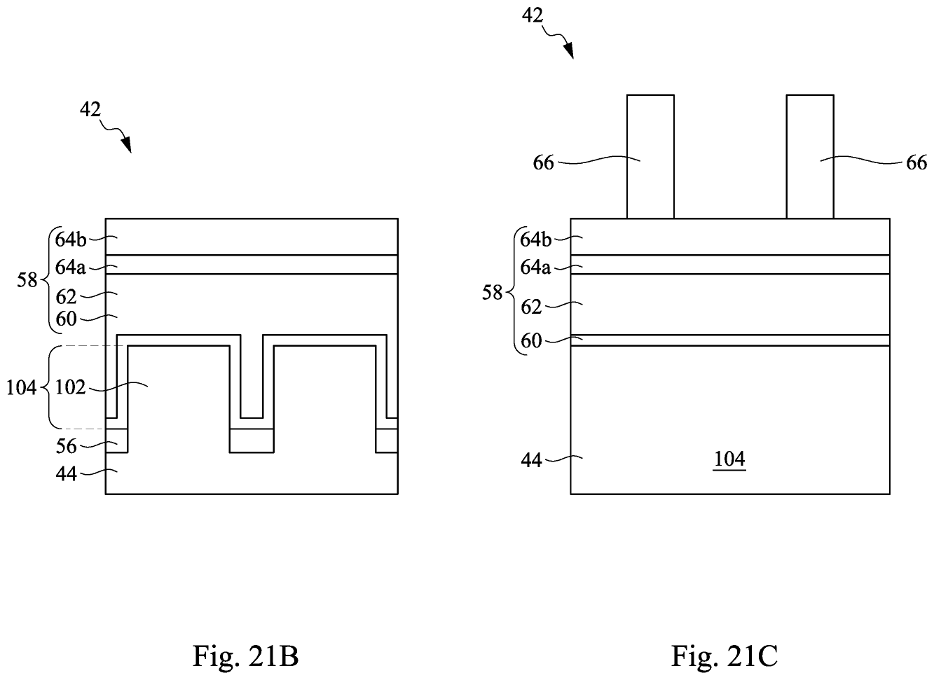

FIGS. 17-20 are cross-sectional views of a semiconductor device 42 in an intermediate stage of fabrication in accordance with some embodiments of the present disclosure. FIG. 21A is a perspective view of the semiconductor device 42 in an intermediate stage of fabrication in accordance with some embodiments of the present disclosure. FIGS. 21B and 21C are cross-sectional views along line a1-a1 and line b1-b1 of FIG. 21A, respectively, in accordance with various aspects of the present disclosure.

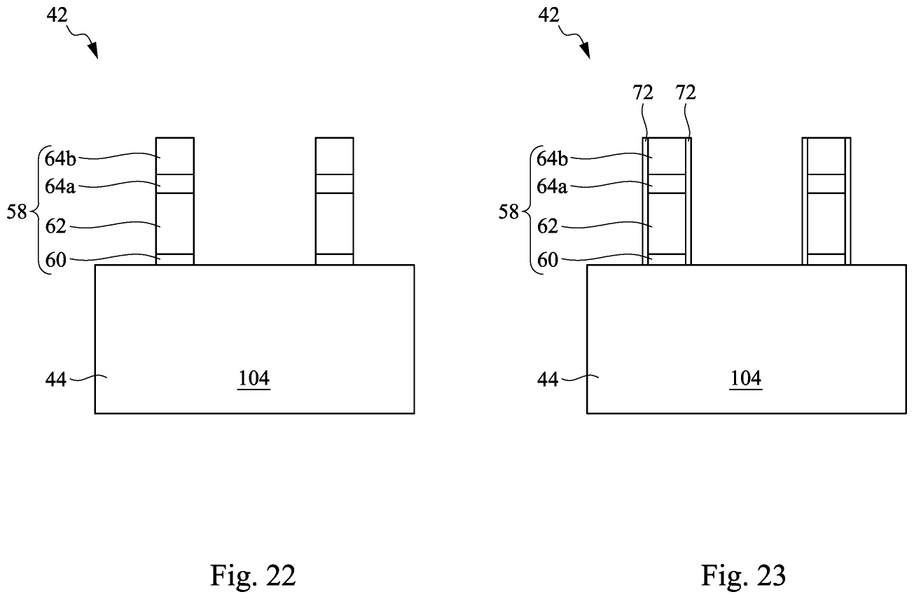

FIGS. 22-25 are cross-sectional views of the semiconductor device 42 in an intermediate stage of fabrication in accordance with some embodiments of the present disclosure.

Reference is made to FIG. 17. A photoresist layer 45 is formed on a substrate 44. The photoresist layer 45 and the substrate 44 are similar to the photoresist layer 114 and the substrate 111 in terms of composition as discussed previously with regard to FIG. 4, and thus the description thereof is omitted herein.

The photoresist layer 45 may be treated to have an increased crosslinking density using the method 1000 in FIG. 3 or the method 1000a in FIG. 13A such that the photoresist layer 45 can have an enhanced mechanical strength to a subsequent etch process performed to etch the substrate 44. The detail of the description thereof is omitted herein.

Reference is made to FIG. 18. An etch process is performed to the substrate 44 using the photoresist layer 45 as an etch mask such that trenches 54 are formed in the substrate 44. The etch process may be a dry etch, a wet etch, or a combination thereof.

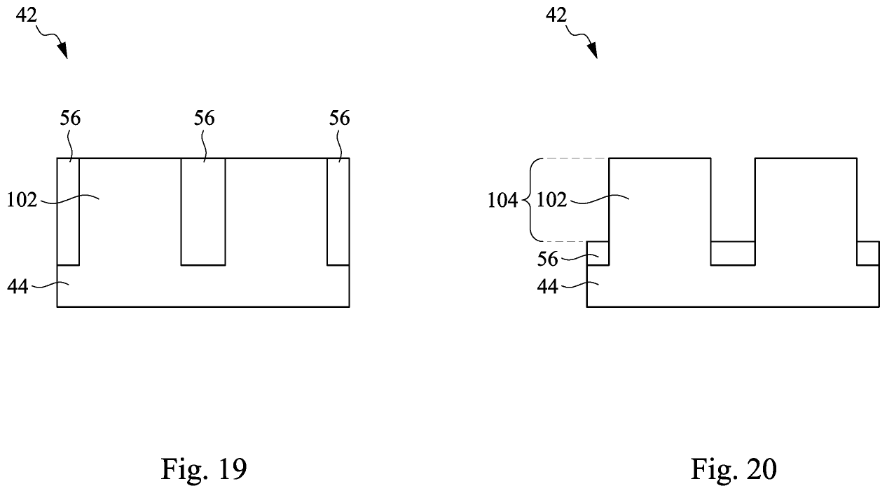

The photoresist layer 45 is removed after etching the substrate 44 by using a suitable photoresist stripper solvent or by a photoresist ashing operation. Isolation regions such as shallow trench isolation (STI) regions 56 may be formed on the substrate 44, filling into the trenches 54. The resulting structure in shown in FIG. 19.

The STI regions 56 may include a liner oxide (not shown). The liner oxide may be formed of a thermal oxide formed through a thermal oxidation of a surface layer of the substrate 44. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 56 may also include a dielectric material over the liner oxide, and the dielectric material may be formed using flowable chemical vapor deposition (FCVD), spin-on coating, or the like.

Referring to FIG. 20, the STI regions 56 are recessed, so that the top portions of semiconductor strips 102 protrude higher than top surfaces of the neighboring STI regions 56 to form protruding fins 104. The etching may be performed using a dry etching process or a wet etching process.

Referring to FIGS. 21A-21C, a dummy gate stack 58 is formed on top surfaces and sidewalls of the protruding fins 104. The dummy gate stack 58 may include a dummy gate dielectric 60 and a dummy gate electrode 62 over the dummy gate dielectric 60. The dummy gate dielectric 60 may be, for example, silicon oxide, silicon nitride, a combination thereof, or the like, and may be deposited or thermally grown according to acceptable techniques. The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material.

The dummy gate dielectric 60 may further include an interfacial layer (not shown) including silicon oxide. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56. The dummy gate stack 58 also has a lengthwise direction perpendicular to the lengthwise directions of protruding fins 104.

A photoresist layer 66 is formed over the dummy gate stack 58. In some embodiments, a pad layer (not shown) and a hard mask layer (not shown) may be formed between the photoresist layer 66 and the dummy gate stack 58. The pad layer and the hard mask layer have an etch selectivity with respect to the photoresist layer 66. The pad layer may be a silicon oxide layer and the hard mask layer may be a silicon nitride layer, for example. The above discussion of the operation to treating the photoresist layer 114 applies to the photoresist layer 66, unless mentioned otherwise. Therefore, the photoresist layer 66 can have an enhanced mechanical strength to etching or bombardment using ion, elements, plasma, or the like. For example, the photoresist layer 66 has an enhanced strength to etching the underlying dummy gate stack 58.

In FIG. 22, using the photoresist layer 66 (see FIG. 21C) as a mask, the pattern of the photoresist layer 66 are extended into the dummy gate stack 58 by etching, using one or more suitable etchants. Due to the photoresist layer 114 having the enhanced mechanical strength to etching, a profile of the photoresist layer 114 remains intact during etching the dummy gate stack 58. In some embodiments, the photoresist layer 66 is removed after etching the dummy gate stack 58 by using a suitable photoresist stripper solvent or by a photoresist ashing operation.

Next, as illustrated in FIG. 23, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

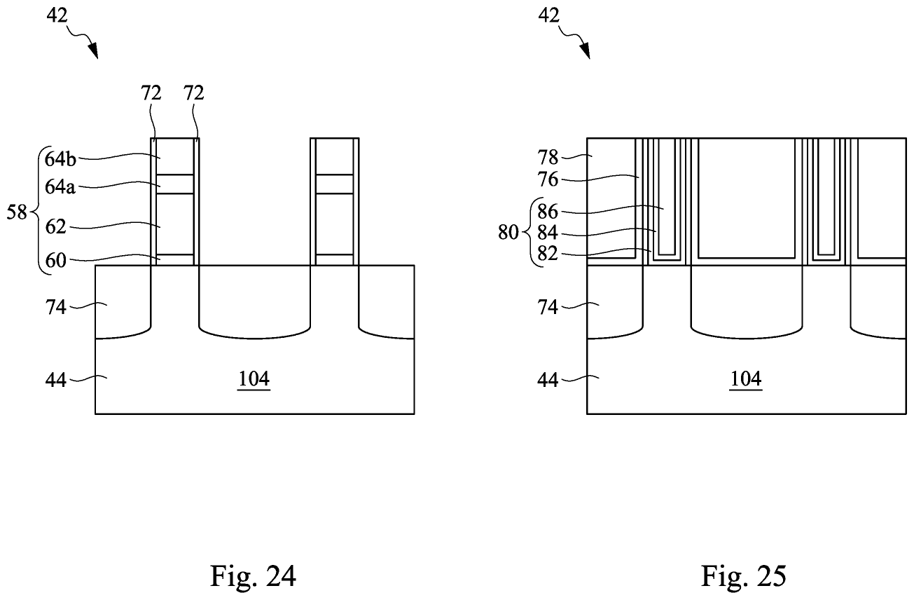

In FIG. 24, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

Next, in FIG. 25, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIGS. 21A-21C) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, replacement gate structures 80 are respectively formed in the gate trenches. The gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 80 forms the gate associated with the three-sides of the channel region provided by the fin 104. Stated another way, each of the gate structures 80 wraps around the fin 104 on three sides. In various embodiments, the high-k/metal gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/metal gate structures 80 may include a metal, metal alloy, or metal silicide. Formation of the high-k/metal gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 84 may include work function metals to provide a suitable work function for the high-k/metal gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by treating the photoresist layer, the photoresist layer can have an increased crosslinking density such that the photoresist layer has an enhanced mechanical strength to etching or bombardment using ion, elements, plasma, or the like.

Another advantage is that the chemical substance 119 including the M-A bonds diffusing into the target layer may increase an etch resistant ability of the target layer such that the target layer may not collapse during etching the target layer.

In some embodiments, a lithography method includes the following steps. A target layer is formed over a substrate. A photoresist composition is applied over the target layer to form a photoresist layer, wherein the photoresist composition comprises a metal-oxide based material. The photoresist layer is exposed to form an exposed region in the photoresist layer. A mixture is applied to the photoresist layer to develop the photoresist layer, wherein the step of applying the mixture to the photoresist layer increases a crosslinking density of the photoresist layer and increases a dissolution contrast of the photoresist layer during developing the photoresist layer by increasing a hydrophilicity of the exposed region. The target layer is etched using the photoresist layer as an etch mask. In some embodiments, the mixture comprises a developer and an additive made of a cation and an anion. In some embodiments, applying the mixture to the photoresist layer is performed such that the target layer comprises a chemical substance including the anion of the additive. In some embodiments, the mixture further comprises an organic solvent, wherein the additive is dissolved in the organic solvent, and the organic solvent comprises (cyclic)alcohols, (cyclic)ketones, (cyclic)esters, (cyclic)ethers, (cyclic)amides, aryls, (cyclic)alkane, or a combination thereof. In some embodiments, the mixture further comprises an organic solvent, wherein the additive is dissolved in the organic solvent, and the organic solvent comprises Propylene glycol methyl ether, Propylene glycol methyl ether acetate, Diacetone alcohol, Methyl N-Amyl Ketone Butyl acetate, gamma-Butyrolactone, Cyclohexanone, toluene, 1-Methyl-2-pyrrolidone, or a combination thereof. In some embodiments, the mixture further comprises water, and the additive is dissolved in the water. In some embodiments, the additive of the mixture comprises HF, HCl, HBr, HI, H₃PO₄, HNO₃, HNO₂, H₂SO₄, H₂SO₃, HClO₄, HClO₃, HBrO₄, HBrO₃, HIO₄, HIO₃, H₃PO₄, H₃PO₃, H₂S, R—COOH, Methanesulfonic acid, or a combination thereof. In some embodiments, the additive of the mixture comprises an organic acid including R—COOH, R in the R—COOH is branched, unbranched or cyclic alkane, alkene or alkyne, aryls with hydroxyl group or halogen substitution. In some embodiments, the cation of the additive is H⁺, Li⁺, Na⁺, K⁺, Be²⁺, Mg²⁺, Ca²⁺, Ti⁴⁺, Fe²⁺, Fe³⁺, Cr³⁺, Cr⁶⁺, Ni²⁺, Ni³⁺, Cu²⁺, Cu²⁺, Ag⁺, Pd²⁺, Pd⁴⁺, Au²⁺, Au⁺, Zn²⁺, B³⁺, Al³⁺, Sn²⁺, Sn³⁺, Sn⁴⁺, Si⁴⁺, N⁺R₁R₂R₃R₄, or a combination thereof, and R₁, R₂, R₃ and R₄ is individually branched, unbranched or cyclic alkane, alkene or alkyne with 1 to 5 carbon atoms. In some embodiments, the anion of the additive is F⁻, Cl⁻, Br⁻, I⁻, OH⁻, CN⁻, SCN⁻, NO₃⁻, NO₂⁻, SO₄⁻², SO₃⁻², ClO₄⁻, ClO₃⁻, BrO₄⁻, BrO₃⁻, IO₄⁻, IO₃⁻, PO₄⁻³, PO₃⁻², S⁻², HS⁻, SR⁻, OR⁻, and R is branched, unbranched or cyclic alkane, alkene or alkyne with 1 to 5 carbon atoms. In some embodiments, applying the mixture to the photoresist layer to develop the photoresist layer comprises applying a developer and a non-developer to the photoresist layer, wherein the non-developer comprises F₂, Cl₂, Br₂, I₂, H₂, Al, Fe, Ni, Cu, Ti, Zn, Cu, He, Ne, Ar, O₂, O₃, or a combination thereof.

In some embodiments, a lithography method includes the following steps. A target layer is formed over a substrate. A photoresist composition is applied over the target layer to form a photoresist layer, wherein the photoresist composition comprises a metal-oxide based material. The photoresist layer is exposed to an EUV radiation. A post-exposure bake operation is performed to the photoresist layer. The photoresist layer is developed. A chemical is applied to the photoresist layer to increase a crosslinking density of the photoresist layer. The chemical comprises F₂, Cl₂, Br₂, I₂, H₂, Ne, Ar, O₂, O₃ or a combination thereof. The target layer is etched using the photoresist layer as an etch mask. In some embodiments, applying the chemical to the photoresist layer is performed before performing the post-exposure bake operation. In some embodiments, applying the chemical to the photoresist layer is performed before developing the photoresist layer. In some embodiments, applying the chemical to the photoresist layer is performed after developing the photoresist layer. In some embodiments, applying the chemical to the photoresist layer and performing the post-exposure bake operation to the photoresist layer are performed at the same time. In some embodiments, the chemical comprises H⁺, Li⁺, Na⁺, K⁺, Be²⁺, Mg²⁺, Ca²⁺, Ti⁴⁺, Fe²⁺, Fe³⁺, Cr³⁺, Cr⁶⁺, Ni²⁺, Ni³⁺, Cu²⁺, Cu²⁺, Ag⁺, Pd²⁺, Pd⁴⁺, Au²⁺, Au⁺, Zn²⁺, B³⁺, Al³⁺, Sn²⁺, Sn³⁺, Sn⁴⁺, Si⁴⁺, N⁺R₁R₂R₃R₄, or a combination thereof, and R₁, R₂, R₃ and R₄ is individually branched, unbranched or cyclic alkane, alkene or alkyne with 1 to 5 carbon atoms. In some embodiments, the chemical comprises F⁻, Cl⁻, Br⁻, I⁻, OH⁻, CN⁻, SCN⁻, NO₃⁻, NO₂⁻, SO₄⁻², SO₃⁻², ClO₄⁻, ClO₃⁻, BrO₄⁻, BrO₃⁻, IO₄⁻, IO₃⁻, PO₄⁻³, PO₃⁻², S⁻², HS⁻, SR⁻, OR⁻, and R is branched, unbranched or cyclic alkane, alkene or alkyne with 1 to 5 carbon atoms.

In some embodiments, an extreme ultraviolet lithography (EUVL) method comprises the following steps. A droplet generator is turned on to eject a metal droplet toward a zone of excitation in front of a collector. A laser source is turned on to emit a laser toward the zone of excitation, such that the metal droplet is heated by the laser to generate EUV radiation. The EUV radiation is guided, by using one or more first optics, toward a reflective mask in an exposure device. The EUV radiation is guided, by using one or more second optics, reflected from the reflective mask toward a photoresist coated substrate in the exposure device. The photoresist has a structure including clusters of metal-oxide resist, and the clusters of the metal-oxide resist bond to H, Li, Na, K, Be, Mg, Ca, Ti, Fe, Fe, Cr, Cr, Ni, Ni, Cu, Cu, Ag, Pd, Pd, Au, Au, Zn, B, Al, Sn, Sn, Sn, Si, N⁺R₁R₂R₃R₄, or a combination thereof, in which R₁, R₂, R₃ and R₄ is individually branched, unbranched or cyclic alkane, alkene or alkyne with 1 to 5 carbon atoms. In some embodiments, the clusters of the metal-oxide resist have a crosslinking framework between metal-oxygen-metal atoms.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography method, comprising:
forming a target layer over a substrate;
applying a photoresist composition over the target layer to form a photoresist layer, wherein the photoresist composition comprises a metal-oxide based material;
exposing the photoresist layer to form an exposed region in the photoresist layer;
applying a mixture to the photoresist layer to develop the photoresist layer, wherein the step of applying the mixture to the photoresist layer increases a crosslinking density of the photoresist layer and increases a dissolution contrast of the photoresist layer during developing the photoresist layer by increasing a hydrophilicity of the exposed region; and
etching the target layer using the photoresist layer as an etch mask.

2. The method of claim 1, wherein the mixture comprises:
a developer; and
an additive made of a cation and an anion.

3. The method of claim 2, wherein:
applying the mixture to the photoresist layer is performed such that the target layer comprises a chemical substance including the anion of the additive.

4. The method of claim 2, wherein the mixture further comprises:
an organic solvent, wherein the additive is dissolved in the organic solvent, and the organic solvent comprises (cyclic)alcohols, (cyclic)ketones, (cyclic)esters, (cyclic)ethers, (cyclic)amides, aryls, (cyclic)alkane, or a combination thereof.

5. The method of claim 3, wherein the mixture further comprises:
an organic solvent, wherein the additive is dissolved in the organic solvent, and the organic solvent comprises Propylene glycol methyl ether, Propylene glycol methyl ether acetate, Diacetone alcohol, Methyl N-Amyl Ketone Butyl acetate, gamma-Butyrolactone, Cyclohexanone, toluene, 1-Methyl-2-pyrrolidone, or a combination thereof.

6. The method of claim 3, wherein the mixture further comprises water, and the additive is dissolved in the water.

7. The method of claim 3, wherein the additive of the mixture comprises HF, HCl, HBr, HI, H₃PO₄, HNO₃, HNO₂, H₂SO₄, H₂SO₃, HClO₄, HClO₃, HBrO₄, HBrO₃, HIO₄, HIO₃, H₃PO₄, H₃PO₃, H₂S, R—COOH, Methanesulfonic acid, or a combination thereof.

8. The method of claim 3, wherein the additive of the mixture comprises an organic acid including R—COOH, R in the R—COOH is branched, unbranched or cyclic alkane, alkene or alkyne, aryls with hydroxyl group or halogen substitution.

9. The method of claim 3, wherein the cation of the additive is H⁺, Li⁺, Na⁺, K⁺, Be²⁺, Mg²⁺, Ca²⁺, Ti⁴⁺, Fe²⁺, Fe³⁺, Cr³⁺, Cr⁶⁺, Ni²⁺, Ni³⁺, Cu²⁺, Cu²⁺, Ag⁺, Pd²⁺, Pd⁴⁺, Au²⁺, Au⁺, Zn²⁺, B³⁺, Al³⁺, Sn²⁺, Sn³⁺, Sn⁴⁺, Si⁴⁺, N⁺R₁R₂R₃R₄, or a combination thereof, and R₁, R₂, R₃ and R₄ is individually branched, unbranched or cyclic alkane, alkene or alkyne with 1 to 5 carbon atoms.

10. The method of claim 3, wherein the anion of the additive is F⁻, Cl⁻, Br⁻, I⁻, OH⁻, CN⁻, SCN⁻, NO₃⁻, NO₂⁻, SO₄⁻², SO₃⁻², ClO₄⁻, ClO₃⁻, BrO₄⁻, BrO₃⁻, IO₄⁻, IO₃⁻, PO₄⁻³, PO₃⁻², S⁺², HS⁻, SR⁻, OR⁻, and R is branched, unbranched or cyclic alkane, alkene or alkyne with 1 to 5 carbon atoms.

11. The method of claim 1, wherein applying the mixture to the photoresist layer to develop the photoresist layer comprises:
applying a developer and a non-developer to the photoresist layer, wherein the non-developer comprises F₂, Cl₂, Br₂, I₂, H₂, Al, Fe, Ni, Cu, Ti, Zn, Cu, He, Ne, Ar, O₂, or a combination thereof.

12. A lithography method, comprising:
forming a target layer over a substrate;
applying a photoresist composition over the target layer to form a photoresist layer, wherein the photoresist composition comprises a metal-oxide based material;
exposing the photoresist layer to an EUV radiation;
performing a post-exposure bake operation to the photoresist layer;
developing the photoresist layer;
applying a chemical to the photoresist layer to increase a crosslinking density of the photoresist layer, wherein the chemical comprises F₂, Cl₂, Br₂, I₂, H₂, Ne, Ar, O₂, O₃ or a combination thereof; and
etching the target layer using the photoresist layer as an etch mask.

13. The method of claim 12, wherein applying the chemical to the photoresist layer is performed before performing the post-exposure bake operation.

14. The method of claim 12, wherein applying the chemical to the photoresist layer is performed before developing the photoresist layer.

15. The method of claim 12, wherein applying the chemical to the photoresist layer is performed after developing the photoresist layer.

16. The method of claim 12, wherein applying the chemical to the photoresist layer and performing the post-exposure bake operation to the photoresist layer are performed at the same time.

17. The method of claim 12, wherein the chemical comprises H⁺, Li⁺, Na⁺, K⁺, Be²⁺, Mg²⁺, Ca²⁺, Ti⁴⁺, Fe²⁺, Fe³⁺, Cr³⁺, Cr⁶⁺, Ni²⁺, Ni³⁺, Cu²⁺, Cu²⁺, Ag⁺, Pd²⁺, Pd⁴⁺, Au²⁺, Au⁺, Zn²⁺, B³⁺, Al³⁺, Sn²⁺, Sn³⁺, Sn⁴⁺, Si⁴⁺, N⁺R₁R₂R₃R₄, or a combination thereof, and R₁, R₂, R₃ and R₄ is individually branched, unbranched or cyclic alkane, alkene or alkyne with 1 to 5 carbon atoms.

18. The method of claim 12, wherein the chemical comprises F⁻, Cl⁻, Br⁻, I⁻, OH⁻, CN⁻, SCN⁻, NO₃⁻, NO₂⁻, SO₄⁻², SO₃⁻², ClO₄⁻, ClO₃⁻, BrO₄⁻, BrO₃⁻, IO₄⁻, IO₃⁻, PO₄⁻³, PO₃⁻², S⁻², HS⁻, SR⁻, OR⁻, and R is branched, unbranched or cyclic alkane, alkene or alkyne with 1 to 5 carbon atoms.

19. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist coated substrate in the exposure device, wherein the photoresist has a structure including clusters of metal-oxide resist, and the clusters of the metal-oxide resist bond to H, Li, Na, K, Be, Mg, Ca, Ti, Fe, Fe, Cr, Cr, Ni, Ni, Cu, Cu, Ag, Pd, Pd, Au, Au, Zn, B, Al, Sn, Sn, Sn, Si, N⁺R₁R₂R₃R₄, or a combination thereof, in which R₁, R₂, R₃ and R₄ is individually branched, unbranched or cyclic alkane, alkene or alkyne with 1 to 5 carbon atoms.

20. The method of claim 19, wherein the clusters of the metal-oxide resist have a crosslinking framework between metal-oxygen-metal atoms.
